(19) United States
(12) Patent Application Publication
(10) Pub. No.: US 2013/0306987 A1
(43) Pub. Date: Nov. 21, 2013

(54) SILICON CARBIDE SEMICONDUCTOR DEVICE AND METHOD FOR MANUFACTURING SAME

(71) Applicant: SUMITOMO ELECTRIC INDUSTRIES, LTD., Osaka-shi (JP)

(72) Inventors: Keiji Wada, Osaka-shi (JP); Takeyoshi Masuda, Osaka-shi (JP); Toru Hiyoshi, Osaka-shi (JP)

(73) Assignee: Sumitomo Electric Industries, Ltd., Osaka-shi (JP)

(21) Appl. No.: 13/863,091

(22) Filed: Apr. 15, 2013

Related U.S. Application Data
(60) Provisional application No. 61/649,086, filed on May 18, 2012.

(30) Foreign Application Priority Data
May 18, 2012 (JP) 2012-113941

(51) Int. Cl. H01L 29/78; H01L 29/66

(52) U.S. Cl. CPC H01L 29/7827; H01L 29/66477
USPC 257/77; 438/270

(57) ABSTRACT

A first layer is of a first conductivity type. A second layer is provided on the first layer and is of a second conductivity type. A third layer is provided on the second layer and isolated from the first layer by the second layer, and is of the first conductivity type. A trench is formed through the third layer and the second layer to reach the first layer. The first layer includes a relaxation region sandwiching a gate insulating film between itself and a gate electrode. The relaxation region is doped with a first impurity for providing the first conductivity type. The relaxation region is also doped with a second impurity for providing the second conductivity type in a concentration lower than that of the first impurity. As a result, an electric field relaxation structure for improving the breakdown voltage can be readily formed.

### BACKGROUND OF THE INVENTION

1. Field of the Invention

The present invention relates to silicon carbide semiconductor devices and methods for manufacturing the same, and particularly to a silicon carbide semiconductor device including a silicon carbide substrate having a trench and a method for manufacturing the same.

2. Description of the Background Art

The breakdown phenomenon in a gate insulating film is considered to be a main factor likely to cause a breakdown in a silicon carbide semiconductor device having a trench gate insulating film. As disclosed in Japanese Patent Laying-Open No. 2009-117593, for example, breakdown of a gate insulating film in a corner portion of a trench due to an electric field is recognized as a problem for a trench type MOSFET (Metal Oxide Semiconductor Field Effect Transistor) made of silicon carbide.

According to the technique described in the above publication, a p⁺ type deep layer deeper than the trench is provided in order to relax the electric field. For this purpose, a trench for providing the p⁺ type deep layer is formed, followed by epitaxial growth to fill this trench. In another technique according to Japanese Patent Laying-Open No. 2008-270681, for example, a p⁺ region is provided at the bottom of a trench by ion implantation.

According to the technique described in Japanese Patent Laying-Open No. 2009-117593, the step of forming the trench for the p⁺ type deep layer and the step of filling this trench are required. In other words, burdensome steps of fine processing and epitaxial growth are required.

According to the technique described in Japanese Patent Laying-Open No. 2008-270681, the ion implantation for forming the p⁺ region needs to be selectively performed into the bottom of the trench. This p⁺ region may become connected to a p region forming a channel in the trench due to manufacturing variations. In this case, a channel structure is substantially altered, causing a major disturbance in characteristics of a semiconductor device. This problem will become more pronounced as the size of the trench is further reduced.

### SUMMARY OF THE INVENTION

The present invention has been made to solve the problems such as described above, and an object of the present invention is to provide a silicon carbide semiconductor device having an electric field relaxation structure that can be readily formed and a method for manufacturing the same.

A silicon carbide semiconductor device according to the present invention includes a silicon carbide substrate, a gate electrode, and a gate insulating film. The silicon carbide substrate includes first to third layers. The first layer is of a first conductivity type. The second layer is provided on the first layer, and is of a second conductivity type. The third layer is provided on the second layer and isolated from the first layer by the second layer, and is of the first conductivity type. The silicon carbide substrate is provided with a trench. The trench is formed through the third layer and the second layer to reach the first layer. The gate electrode is embedded in the trench. The gate insulating film separates the silicon carbide substrate from the gate electrode in the trench. The first layer includes a relaxation region sandwiching the gate insulating film between itself and the gate electrode. The relaxation region is doped with a first impurity for providing the first conductivity type. The relaxation region is also doped with a second impurity for providing the second conductivity type in a concentration lower than that of the first impurity.

According to the above-described silicon carbide semiconductor device, the relaxation region for relaxing an electric field is formed in the vicinity of the trench in the first layer. This relaxation region is of the first conductivity type, not the second conductivity type. If the relaxation region is of the second conductivity type and becomes connected to the second layer, the second layer as a region of the second conductivity type is enlarged, causing a major disturbance in characteristics of a channel formed on the second region. In the above-described silicon carbide semiconductor device, however, the relaxation region is of the first conductivity type and thus does not greatly affect the channel characteristics even when connected to the second layer. Thus, high accuracy is not required for the position where the relaxation region is to be formed. Accordingly, the relaxation region can be readily formed. Preferably, the relaxation region has a concentration of the second impurity of not less than 1×10¹⁴ cm⁻³. As a result, the electric field applied to the gate insulating film can be further relaxed.

Preferably, in at least a portion of the relaxation region, a value obtained by subtracting the concentration of the second impurity from the concentration of the first impurity is not more than 10% of the concentration of the first impurity. As a result, the electric field applied to the gate insulating film can be further relaxed.

Preferably, the relaxation region has a thickness of not less than 200 nm. As a result, the electric field applied to the gate insulating film can be further relaxed.

Preferably, the trench has a tapered shape and expands toward an opening side. As a result, ions can be readily implanted into the trench. Thus, the formation of the relaxation region on the trench can be readily performed by ion implantation.

A method for manufacturing a silicon carbide semiconductor device according to the present invention includes the following steps. A silicon carbide substrate is formed that includes a first layer of a first conductivity type, a second layer of a second conductivity type provided on the first layer, and a third layer of the first conductivity type provided on the second layer and isolated from the first layer by the second layer. The first layer is doped with a first impurity to provide the first layer with the first conductivity type. A trench is formed through the third layer and the second layer to reach the first layer and have a bottom on the first layer. A relaxation region is formed on the bottom by implanting a second impurity for providing the second conductivity type through the bottom of the trench into the first layer. The formation of a relaxation region is performed in such a manner that the concentration of the second impurity is lower than the concentration of the first impurity in the relaxation region. A gate insulating film is formed to cover an inner surface of the trench of the silicon carbide substrate. A gate electrode is formed on the gate insulating film.

According to the above-described manufacturing method, the relaxation region for relaxing an electric field is formed in the vicinity of the trench in the first layer. This relaxation region is of the first conductivity type, not the second conductivity type. If the relaxation region is of the second conductivity type and becomes connected to the second layer due to manufacturing variations, the second layer as a region of the second conductivity type is enlarged, causing a major disturbance in characteristics of a channel formed on the second region. In the above-described silicon carbide semiconductor device, however, the relaxation region is of the first conductivity type and thus does not greatly affect the channel characteristics even when connected to the second layer. Thus, high accuracy is not required for the position where the relaxation region is to be formed. Accordingly, the relaxation region can be readily formed.

Preferably, the formation of a relaxation region is performed by implanting the second impurity into the entire inner surface of the trench. Thus, it is unnecessary to form a mask to selectively cover a portion of the inner surface of the trench. Accordingly, the manufacturing method is further simplified.

According to the present invention as described above, the electric field relaxation structure can be readily formed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a partial cross-sectional view schematically showing the structure of a silicon carbide semiconductor device in one embodiment of the present invention.

FIG. 2 is a perspective view schematically showing the shape of a silicon carbide substrate of FIG. 1.

FIG. 3 is a diagram where p type surfaces are provided with hatching in the perspective view of FIG. 2.

FIG. 4 is an enlarged view of FIG. 1.

FIG. 5 shows an example of an acceptor concentration profile along an arrow Z1 in FIG. 4.

FIG. 6 shows an example of an effective impurity concentration profile along arrow Z1 in FIG. 4.

FIG. 7 shows an example of the effective impurity concentration profile along an arrow Z2 in FIG. 4.

FIG. 8 shows electric field strength in positions along arrow Z1 in FIG. 4 according to a comparative example.

FIG. 9 shows electric field strength in positions along arrow Z1 in FIG. 4 according to an embodiment.

FIG. 10 is a partial cross-sectional view schematically showing a first step of a method for manufacturing the silicon carbide semiconductor device of FIG. 1.

FIG. 11 is a partial cross-sectional view schematically showing a second step of the method for manufacturing the silicon carbide semiconductor device of FIG. 1.

FIG. 12 is a partial cross-sectional view schematically showing a third step of the method for manufacturing the silicon carbide semiconductor device of FIG. 1.

FIG. 13 is a partial cross-sectional view schematically showing a fourth step of the method for manufacturing the silicon carbide semiconductor device of FIG. 1.

FIG. 14 is a partial cross-sectional view schematically showing a fifth step of the method for manufacturing the silicon carbide semiconductor device of FIG. 1.

FIG. 15 is a partial cross-sectional view schematically showing a sixth step of the method for manufacturing the silicon carbide semiconductor device of FIG. 1.

FIG. 16 is a partial cross-sectional view schematically showing a seventh step of the method for manufacturing the silicon carbide semiconductor device of FIG. 1.

FIG. 17 is a partial cross-sectional view schematically showing an eighth step of the method for manufacturing the silicon carbide semiconductor device of FIG. 1.

FIG. 18 is a partial cross-sectional view schematically showing a ninth step of the method for manufacturing the silicon carbide semiconductor device of FIG. 1.

FIG. 19 is a partial cross-sectional view schematically showing a tenth step of the method for manufacturing the silicon carbide semiconductor device of FIG. 1.

FIG. 20 is a partial cross-sectional view schematically showing an eleventh step of the method for manufacturing the silicon carbide semiconductor device of FIG. 1.

FIG. 21 is a partial cross-sectional view schematically showing a fine structure of a surface of the silicon carbide substrate included in the silicon carbide semiconductor device.

FIG. 22 shows a crystal structure of the (000-1) plane in a hexagonal crystal of polytype 4H.

FIG. 23 shows a crystal structure of the (11-20) plane along a line XXIII-XXIII in FIG. 22.

FIG. 24 shows a crystal structure in the (11-20) plane in the vicinity of a surface of a combined plane of FIG. 18.

FIG. 25 shows the combined plane of FIG. 18 when viewed from the (01-10) plane.

FIG. 26 is a graph chart showing one exemplary relation between channel mobility and an angle between the channel surface and the (000-1) plane when viewed macroscopically, in each of a case where thermal etching is performed and a case where thermal etching is not performed.

FIG. 27 is a graph chart showing one exemplary relation between channel mobility and an angle between the channel direction and the <0-11-2> direction.

FIG. 28 shows a variation of FIG. 21.

### DESCRIPTION OF THE PREFERRED EMBODIMENTS

The embodiments of the present invention will be described hereinafter with reference to the drawings. It is noted that the same or corresponding parts are designated by the same reference numbers in the following drawings, and description thereof will not be repeated. Regarding crystallographic descriptions in the present specification, an individual orientation is represented by [ ], a group orientation is represented by < >, an individual plane is represented by ( ) and a group plane is represented by { }. In addition, although a negative crystallographic index is usually indicated by putting “-” (bar) above a numeral, it is indicated by putting a negative sign before the numeral in the present specification.

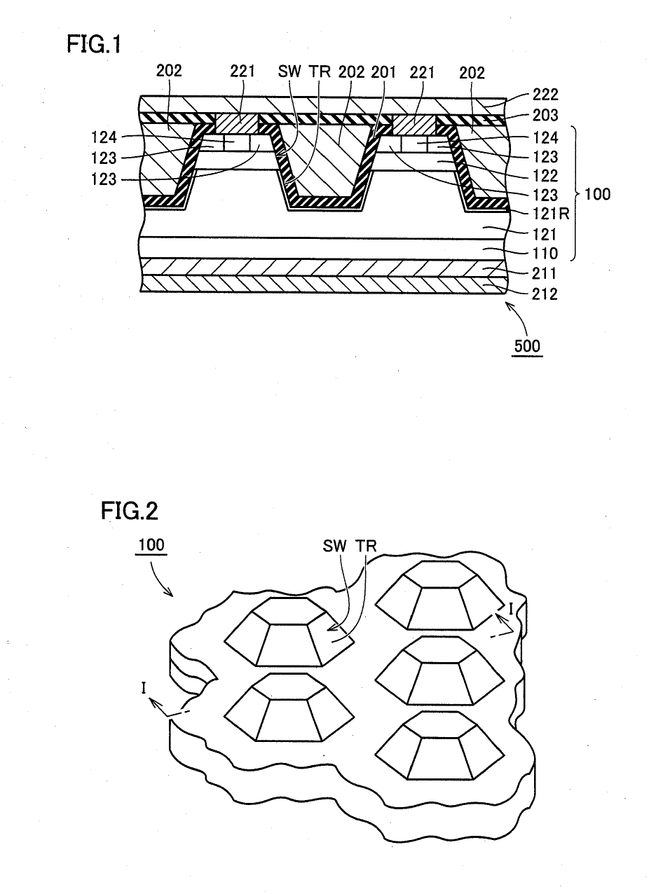

As shown in FIG. 1, a vertical type MOSFET 500 (silicon carbide semiconductor device) in this embodiment includes an epitaxial substrate 100 (silicon carbide substrate), a gate oxide film 201 (gate insulating film), a gate electrode 202, an interlayer insulating film 203, a source electrode 221, a drain electrode 211, a source line 222, and a protection electrode 212.

Epitaxial substrate 100 has a single-crystal substrate 110 and an epitaxial layer provided thereon. The epitaxial layer includes an n⁻ layer 121 (first layer), a p type body layer 122 (second layer), an n region 123 (third layer), and a contact region 124.

Epitaxial substrate 100 is made of silicon carbide. This silicon carbide preferably has a hexagonal crystal structure, and more preferably has a polytype 4H.

Single-crystal substrate 110 is of n type (first conductivity type). Single-crystal substrate 110 has one main surface (upper surface in FIG. 1) having a plane orientation which preferably corresponds substantially to the (000-1) plane.

N⁻ layer 121 is doped with a donor (first impurity) serving as an impurity for providing n type (first conductivity type), so that n⁻ layer 121 is of n type. N⁻ layer 121 is doped with the donor preferably during epitaxial growth of n⁻ layer 121, rather than by ion implantation. N⁻ layer 121 preferably has a donor concentration lower than that in single-crystal substrate 110. The donor concentration in n⁻ layer 121 is preferably not less than 1×10¹⁵ cm⁻³ and not more than 5×10¹⁶ cm⁻³, and is set to 8×10¹⁵ cm⁻³, for example. N⁻ layer 121 has a relaxation region 121R. Relaxation region 121R will be described later in detail.

P type body layer 122 is provided on n⁻ layer 121, and is of p type (second conductivity type). P type body layer 122 has an acceptor concentration of, for example, 1×10¹⁸ cm⁻³.

N region 123 is of n type (first conductivity type). N region 123 is provided on p type body layer 122, and is isolated from n⁻ layer 121 by p type body layer 122. Contact region 124 is of p type. Contact region 124 is formed on a portion of p type body layer 122 so as to be connected to p type body layer 122.

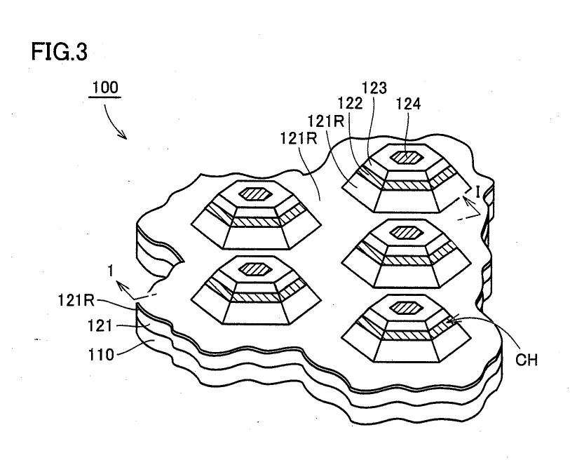

Referring additionally to FIGS. 2 and 3, epitaxial substrate 100 has a trench TR formed through n region 123 and p type body layer 122 to reach n⁻ layer 121. Trench TR has a side wall having a surface SW. In this embodiment, trench TR further has a flat bottom. Surface SW includes a channel surface on p type body layer 122. Preferably, surface SW has a predetermined crystal plane (also referred to as “special plane”). The special plane will be described later in detail.

That epitaxial substrate 100 has trench TR corresponds to the fact that the epitaxial layer has been partially removed in the upper surface of single-crystal substrate 110. In this embodiment, a large number of mesa structures are formed on the upper surface of single-crystal substrate 110. Specifically, each mesa structure has an upper surface and a bottom surface each in a hexagonal shape, and has a side wall inclined relative to the upper surface of single-crystal substrate 110. As such, trench TR has a tapered shape and expands toward the opening side.

Gate oxide film 201 (FIG. 1) covers trench TR. Specifically, gate oxide film 201 is provided on surface SW and the bottom of trench TR. This gate oxide film 201 extends onto the upper surface of n region 123. Gate electrode 202 is embedded in trench TR. Gate oxide film 201 separates epitaxial substrate 100 from gate electrode 202 in trench TR. Gate electrode 202 faces surface SW of p type body layer 122, with gate oxide film 201 interposed therebetween. Gate electrode 202 has an upper surface substantially as high as the upper surface of a portion of gate oxide film 201 on the upper surface of n region 123. Interlayer insulating film 203 is provided to cover gate electrode 202 as well as the portion of gate oxide film 201 that extends onto the upper surface of n region 123.

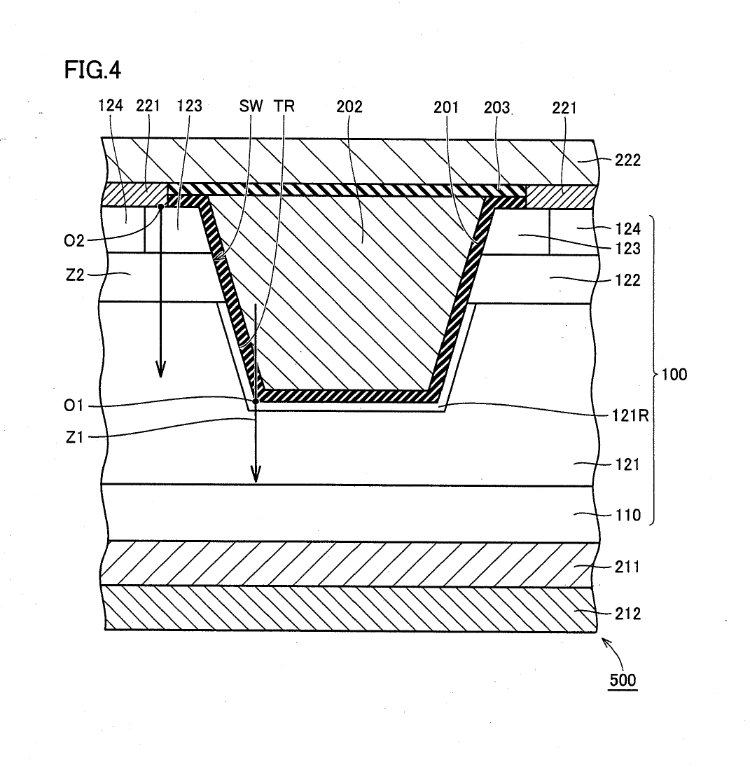

As shown in FIG. 4, relaxation region 121R included in n⁻ layer 121 sandwiches gate oxide film 201 between itself and gate electrode 202. In this embodiment, relaxation region 121 R is provided in n⁻ layer 121 along the entire inner surface of trench TR. Relaxation region 121R is thus provided on the bottom of trench TR, particularly in corner portions of the bottom. Relaxation region 121R is doped with the donor as with the portion of n⁻ layer 121 other than relaxation region 121R. Relaxation region 121R is also doped with an acceptor (second impurity) serving as an impurity for providing p type (second conductivity type) in a concentration lower than that of the donor. Consequently, the doped donor is partially canceled by the acceptor in relaxation region 121R.

Relaxation region 121R preferably has an acceptor concentration of not less than 1×10¹⁴ cm⁻³. Preferably, in at least a portion of relaxation region 121R, a value obtained by subtracting the concentration of the acceptor (second impurity) from the concentration of the donor (first impurity), namely, an effective impurity concentration, is not more than 10% of the donor concentration. Preferably, relaxation region 121R has a thickness of not less than 200 nm.

Referring further to FIGS. 5 to 7, examples of impurity concentrations in epitaxial substrate 100 are described in detail.

FIG. 5 shows an example of a profile of an acceptor concentration Nₚ in a depth direction (arrow Z1 in FIG. 4) from a point O1 at the border between gate oxide film 201 and n⁻ layer 121 in a corner portion of trench TR. In this case, relaxation region 121R having an acceptor concentration of not less than 1×10¹⁴ cm⁻³ (FIG. 4) is formed with a thickness Dₘ from the border between gate oxide film 201 and n⁻ layer 121. Preferably, thickness Dₘ is not less than 200 nm. Preferably, an acceptor concentration N₁ at point O1 is not less than 1×10¹⁴ cm⁻³. Preferably, a maximum acceptor concentration N_{K} in relaxation region 121R is not less than 90% of the donor concentration in relaxation region 121R.

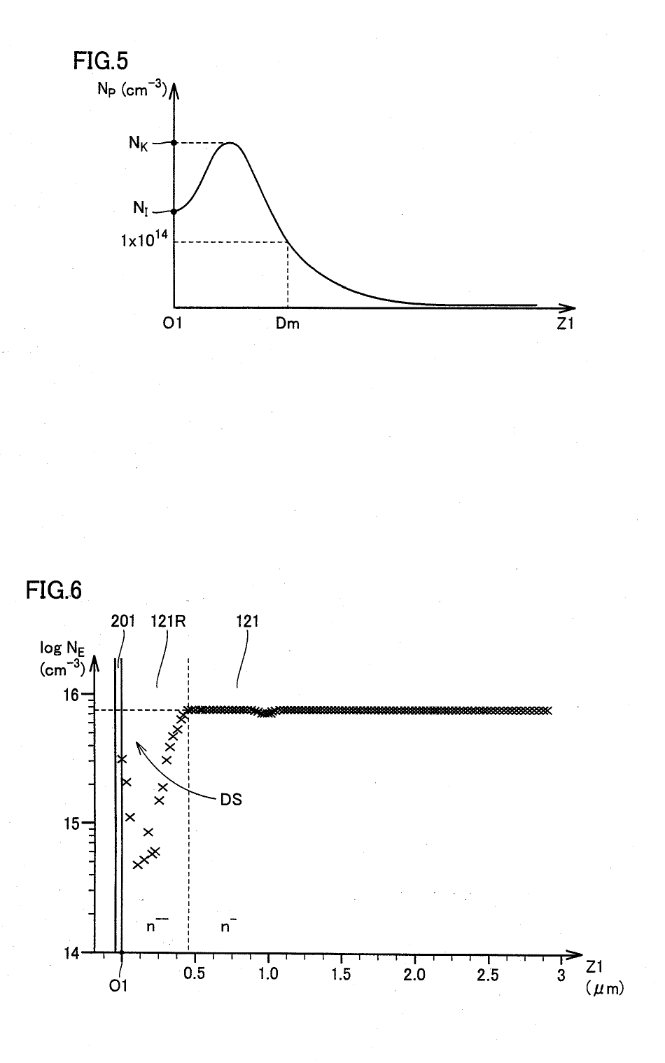

FIG. 6 shows an example of a profile of an effective impurity concentration N_{E} along arrow Z1 (FIG. 4). As a result of providing the profile of acceptor concentration Nₚ such as shown in FIG. 5, effective impurity concentration N_{E} in relaxation region 121R is low compared to that in the portion of n⁻ layer 121 other than relaxation region 121 R. A value obtained by integrating a drop in effective impurity concentration N_{E} in relaxation region 121 R in a horizontal axis direction, indicated by an arrow DS (FIG. 6), corresponds to a dose amount of the acceptor implanted to form relaxation region 121R.

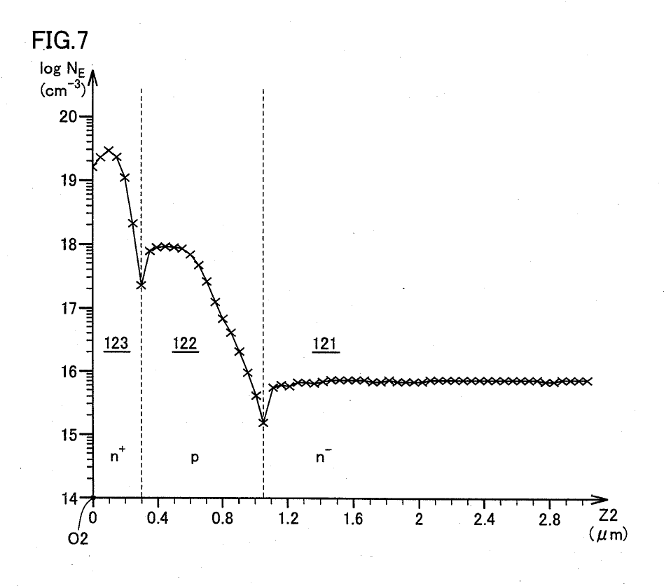

FIG. 7 shows a profile of effective impurity concentration N_{E} along a thickness direction (arrow Z2 in FIG. 4) in positions away from trench TR. As illustrated in this profile, the effective impurity concentration in p type body layer 122 and n region 123 is much higher than in n⁻ layer 121. For this reason, even if the acceptor is implanted not only into n⁻ layer 121 but also to p type body layer 122 and n region 123 as in this embodiment during the acceptor implantation for forming relaxation region 121R (FIG. 5), this implantation does not greatly affect p type body layer 122 and n region 123.

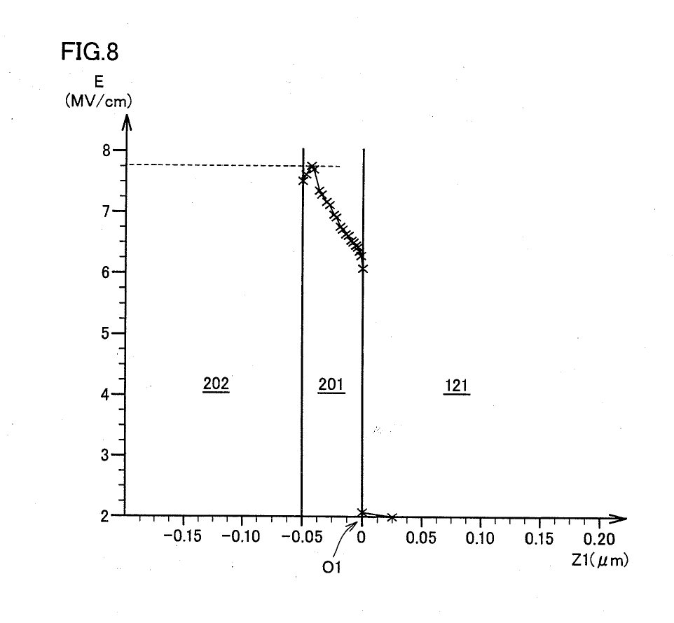

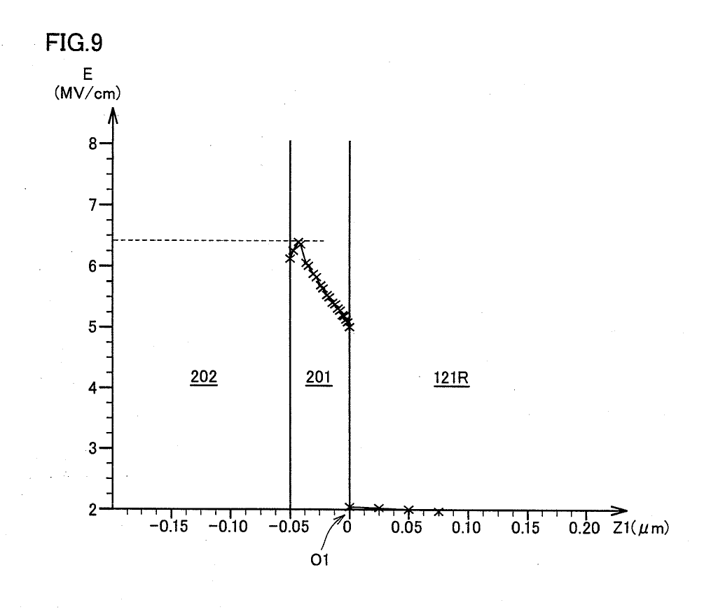

An example of simulation results of electric field strength in gate oxide film 201 while MOSFET 500 is in an off state is now described. FIG. 8 shows an example of simulation results of electric field strength E in positions along arrow Z1 (FIG. 4), in a case where relaxation region 121R was not provided (comparative example). Electric field strength E in gate oxide film 201 had a maximum value of 7.8 MV/cm. FIG. 9 shows an example of simulation results of electric field strength E in positions along arrow Z1 (FIG. 4), in a case where relaxation region 121R was provided (embodiment). Electric field strength E in gate oxide film 201 had a maximum value of 6.4 MV/cm. It was thus found that the maximum value of electric field strength E could be lowered from 7.8 MV/cm to 6.4 MV/cm by providing relaxation region 121R.

The impurity profiles shown in FIGS. 6 and 7 were used in this simulation. The depth of trench TR was set to 1.8 μm. The drain voltage was set to 600 V.

A method for manufacturing MOSFET 500 (FIG. 1) is now described.

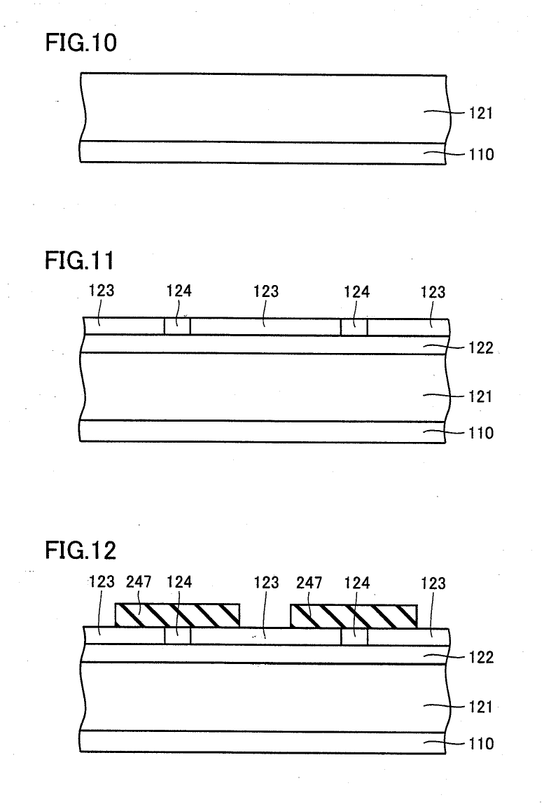

As shown in FIG. 10, n⁻ layer 121 is epitaxially grown on single-crystal substrate 110 to form the epitaxial substrate. This epitaxial growth can be implemented by CVD (Chemical Vapor Deposition) that utilizes a mixed gas of silane (SiH₄) and propane (C₃H₈) as a material gas and utilizes hydrogen gas (H₂) as a carrier gas, for example. In so doing, it is preferable to introduce nitrogen (N) or phosphorus (P), for example, as an impurity of n type conductivity.

As shown in FIG. 11, p type body layer 122 on n⁻ layer 121, n region 123 on p type body layer 122, and contact region 124 are formed. Specifically, ions are implanted into the upper surface of n⁻ layer 121. In the ion implantation for forming p type body layer 122 and contact region 124, ions of an impurity for providing p type such as aluminum (Al) are implanted. In the ion implantation for forming n region 123, ions of an impurity for providing n type such as phosphorus (P) are implanted. It is noted that epitaxial growth which involves doping of an impurity may be performed instead of the ion implantation.

As shown in FIG. 12, a mask layer 247 having an opening is formed on the surface consisting of n region 123 and contact region 124. For example, an insulating film such as a silicon oxide film can be used as mask layer 247. The opening is formed in a position corresponding to the position of trench TR (FIG. 1).

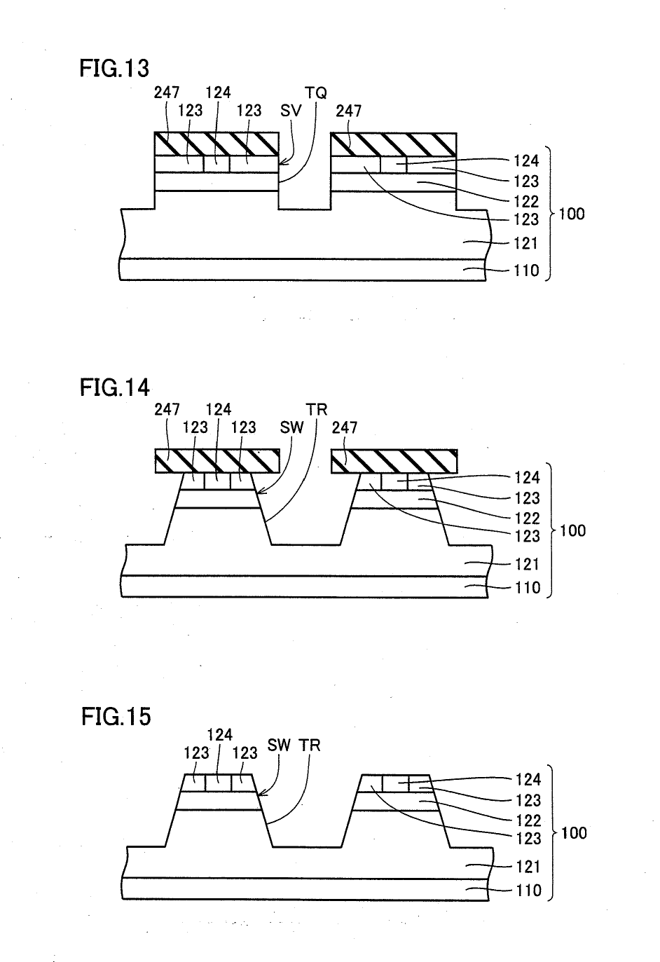

As shown in FIG. 13, n region 123, p type body layer 122, and a portion of n⁻ layer 121 are removed by etching in the opening of mask layer 247. An exemplary, usable etching method is reactive ion etching (RIE), in particular, inductively coupled plasma (ICP) RIE. Specifically, for example, ICP-RIE can be used which employs SF₆ or a mixed gas of SF₆ and O₂ as the reactive gas. By means of such etching, in the region where trench TR (FIG. 1) is to be formed, a recess TQ can be formed which has a side wall having an inner surface SV substantially perpendicular to the main surface of single-crystal substrate 110.

Next, inner surface SV of recess TQ of epitaxial substrate 100 is thermally etched. The thermal etching can be performed, for example, by heating epitaxial substrate 100 in an atmosphere containing reactive gas having at least one or more types of halogen atom. The at least one or more types of halogen atom include at least one of chlorine (Cl) atom and fluorine (F) atom. This atmosphere is, for example, Cl₂, BCL₃, SF₆, or CF₄. For example, the thermal etching is performed using a mixed gas of chlorine gas and oxygen gas as a reactive gas, at a heat treatment temperature of, for example, not less than 700° C. and not more than 1000° C.

As a result of the thermal etching, trench TR is formed as shown in FIG. 14. Here, as the side wall of trench TR, surface SW is formed which has portions respectively formed of n⁻ layer 121, p type body layer 122 and n region 123. In surface SW, the special plane is spontaneously formed.

It is noted that the reactive gas may contain a carrier gas in addition to the chlorine gas and the oxygen gas. An exemplary, usable carrier gas is nitrogen (N₂) gas, argon gas, helium gas, or the like. When the heat treatment temperature is set at not less than 700° C. and not more than 1000° C. as described above, a rate of etching SiC is approximately 70 μm/hour, for example. Moreover, in this case, mask layer 247, which is made of silicon oxide and therefore has a very large selection ratio relative to SiC, is not substantially etched during the etching of SiC. Next, mask layer 247 is removed with an appropriate method such as etching (FIG. 15).

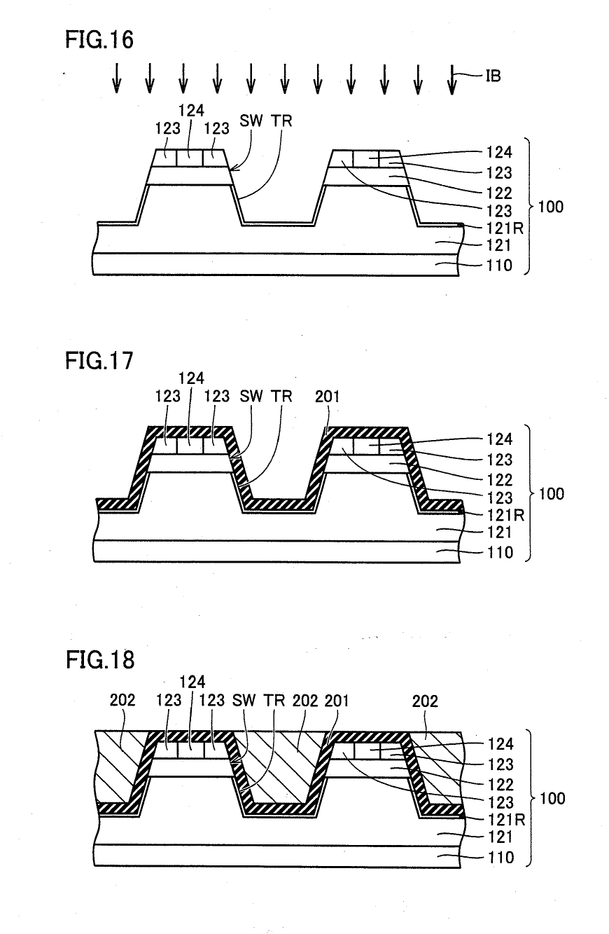

As shown in FIG. 16, the acceptor is implanted through the bottom of trench TR into n⁻ layer 121 by means of ion implantation with an ion beam IB, to form relaxation region 121R on the bottom of trench TR. The acceptor implantation is performed in such a manner that the acceptor concentration is lower than the donor concentration in relaxation region 121R.

In this step, the acceptor may be implanted into a portion or the whole of each of p type body layer 122, n region 123 and contact region 124. P type body layer 122, n region 123 and contact region 124 have the effective impurity concentration much higher than in n⁻ layer 121, and are thus hardly affected by the acceptor implantation in this step. Therefore, this step does not particularly require a highly accurate mask for ion implantation, but can be performed without a mask as illustrated. In this case, the acceptor is implanted into the entire inner surface of trench TR.

Preferably, a dose amount of the implanted acceptor is not less than 1×10¹¹ cm⁻². This ion implantation may be performed in multiple stages. For example, the ion implantation may be performed in four steps with dose amounts of 7×10¹⁰ cm⁻² at 270 keV, 7×10¹⁰ cm⁻² at 180 keV, 5×10¹⁰ cm⁻² at 100 keV, and 3×10¹⁰ cm⁻² at 50 keV, respectively. Next, activation annealing is performed to activate the impurities implanted by the ion implantation.

As shown in FIG. 17, gate oxide film 201 is formed to cover the inner surface of trench TR of epitaxial substrate 100. Gate oxide film 201 is obtained, for example, by thermally oxidizing the epitaxial layer made of silicon carbide.

As shown in FIG. 18, gate electrode 202 is formed on gate oxide film 201 to fill the region in trench TR, with gate oxide film 201 interposed therebetween. A method for forming gate electrode 202 can be performed, for example, by forming a film of conductor and performing CMP (Chemical Mechanical Polishing).

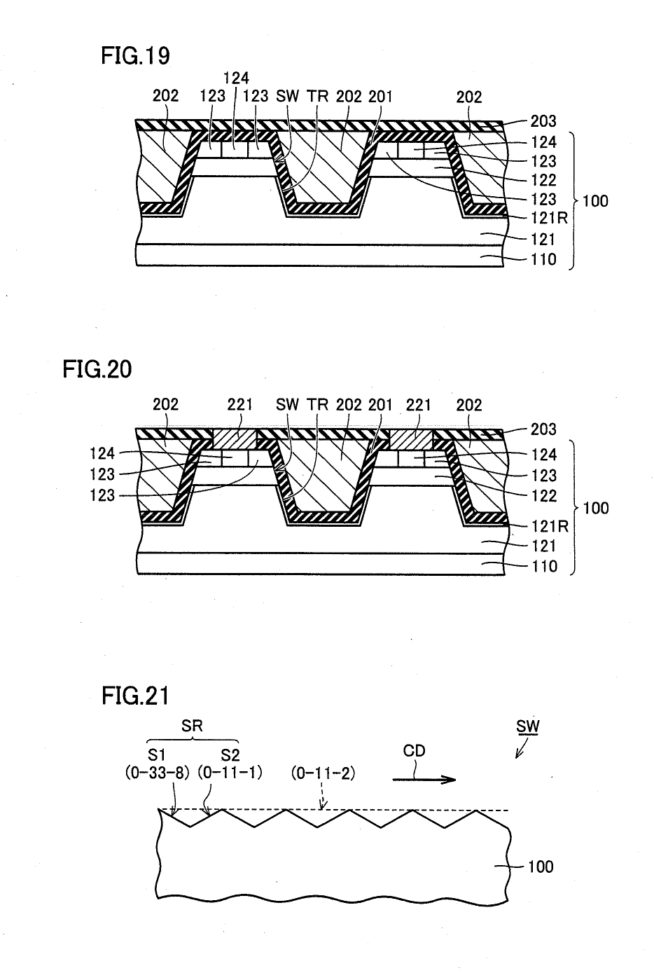

As shown in FIG. 19, interlayer insulating film 203 is formed on gate electrode 202 and gate oxide film 201 to cover the exposed surfaces of gate electrode 202.

Referring to FIG. 20, etching is performed to form openings in interlayer insulating film 203 and gate oxide film 201. Through the openings, n region 123 and contact region 124 in the upper surfaces of the mesa structures are exposed. Next, in the upper surface of each mesa structure, source electrode 221 is formed in contact with n region 123 and contact region 124.

Referring again to FIG. 1, source line 222, drain electrode 211 and protection electrode 212 are formed. MOSFET 500 is thus obtained. According to this embodiment, relaxation region 121R (FIG. 4) is formed in the vicinity of trench TR in n⁻ layer 121. Relaxation region 121R is of n type, not p type. If the relaxation region is of p type and becomes connected to p type body layer 122, p type body layer 122 as a region of p type is enlarged, causing a major disturbance in characteristics of a channel formed on p type body layer 122. In this embodiment, however, relaxation region 121 R is of n type and thus does not greatly affect the channel characteristics even when connected to p type body layer 122 as shown in FIG. 4. Thus, high accuracy is not required for the position where relaxation region 121R is to be formed. Accordingly, relaxation region 121R can be readily formed.

When relaxation region 121R has an acceptor concentration Nₚ (FIG. 5) of not less than 1×10¹⁴ cm⁻³, the electric field applied to gate oxide film 201 can be further relaxed.

When relaxation region 121R at least partially has an effective impurity concentration N_{E} (FIG. 6) of not more than 10% of the donor concentration, the electric field applied to gate oxide film 201 can be further relaxed.

When relaxation region 121R has a thickness of not less than 200 nm (FIG. 6), the electric field applied to gate oxide film 201 can be further relaxed.

When trench TR has a tapered shape and expands toward the opening side (FIG. 4), ion beam IB (FIG. 16) can readily enter trench TR. Accordingly, the formation of relaxation region 121 R on trench TR can be readily performed.

When the formation of relaxation region 121R is performed by implanting the acceptor into the entire inner surface of trench TR (FIG. 16), it is unnecessary to form a mask to selectively cover a portion of the inner surface of trench TR. Accordingly, the manufacturing method is further simplified.

While trench TR in this embodiment has a flat bottom, the shape of the trench is not limited as such, and the bottom may be a recess. For example, the trench may be in a V-shape.

While the first conductivity type is n type and the second conductivity type is p type in this embodiment, these conductivity types may be reversed. In this case, the donor and the acceptor in the description above are also reversed. In order to further improve the channel mobility, however, the first conductivity type is preferably n type.

Furthermore, the silicon carbide semiconductor device may be a MISFET (Metal Insulator Semiconductor Field Effect Transistor) other than the MOSFET. Moreover, the silicon carbide semiconductor device is not limited to the MISFET as long as it has a trench gate structure. For example, the semiconductor device may be a trench type IGBT (Insulated Gate Bipolar Transistor).

(Surface Having Special Plane)

Surface SW of p type body layer 122 (FIG. 4) forming the channel surface is preferably a surface having a special plane. As shown in FIG. 21, such surface SW includes a plane S1 (first plane) having a plane orientation of {0-33-8}. Plane S1 preferably has a plane orientation of (0-33-8).

More preferably, surface SW microscopically includes plane S1, and further microscopically includes a plane S2 (second plane) having a plane orientation of {0-11-1}. The term “microscopically” as used herein means “minutely to such an extent that at least the size about twice as large as an interatomic spacing is considered.” As a method for observing such a microscopic structure, for example, a TEM (Transmission Electron Microscope) can be used. Plane S2 preferably has a plane orientation of (0-11-1).

Preferably, plane S1 and plane S2 of surface SW form a combined plane SR having a plane orientation of {0-11-2}. That is, combined plane SR is formed of periodically repeated planes S1 and S2. Such a periodic structure can be observed, for example, by TEM or AFM (Atomic Force Microscopy). In this case, combined plane SR macroscopically has an off angle of 62° relative to the {000-1} plane. The term “macroscopically” as used herein means “disregarding a fine structure having a size of approximately interatomic spacing.” For the measurement of such a macroscopic off angle, a method employing general X-ray diffraction can be used, for example. Preferably, combined plane SR has a plane orientation of (0-11-2). In this case, combined plane SR macroscopically has an off angle of 62° relative to the (000-1) plane.

Preferably, in the channel surface, carriers flow in a channel direction CD, in which the above-described periodic repetition is done.

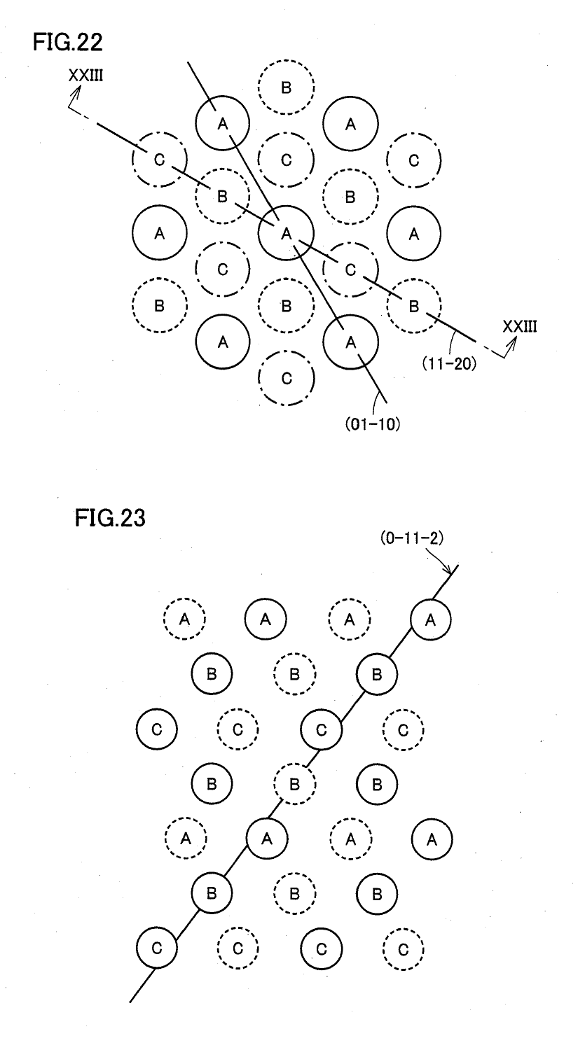

A detailed structure of combined plane SR is now described. Generally, regarding S1 atoms (or C atoms), when a silicon carbide single crystal of polytype 4H is viewed from the (000-1) plane, atoms in a layer A (solid line in the figure), atoms in a layer B (broken line in the figure) disposed therebelow, atoms in a layer C (chain-dotted line in the figure) disposed therebelow, and atoms in a layer B (not shown) disposed therebelow are repeatedly provided as shown in FIG. 22. In other words, with four layers ABCB being regarded as one period, a periodic stacking structure such as ABCBABCBABCB . . . is provided.

As shown in FIG. 23, in the (11-20) plane (cross section taken along a line XXIII-XXIII in FIG. 22), the atoms in each of four layers ABCB constituting the above-described one period are not aligned completely along the (0-11-2) plane. In FIG. 23, the (0-11-2) plane is illustrated to pass through the locations of the atoms in layers B. In this case, it can be seen that each of the atoms in layers A and C is deviated from the (0-11-2) plane. Hence, even when the macroscopic plane orientation of the surface of the silicon carbide single crystal, i.e., the plane orientation thereof with its atomic level structure being disregarded, is limited to (0-11-2), this surface can have various structures microscopically.

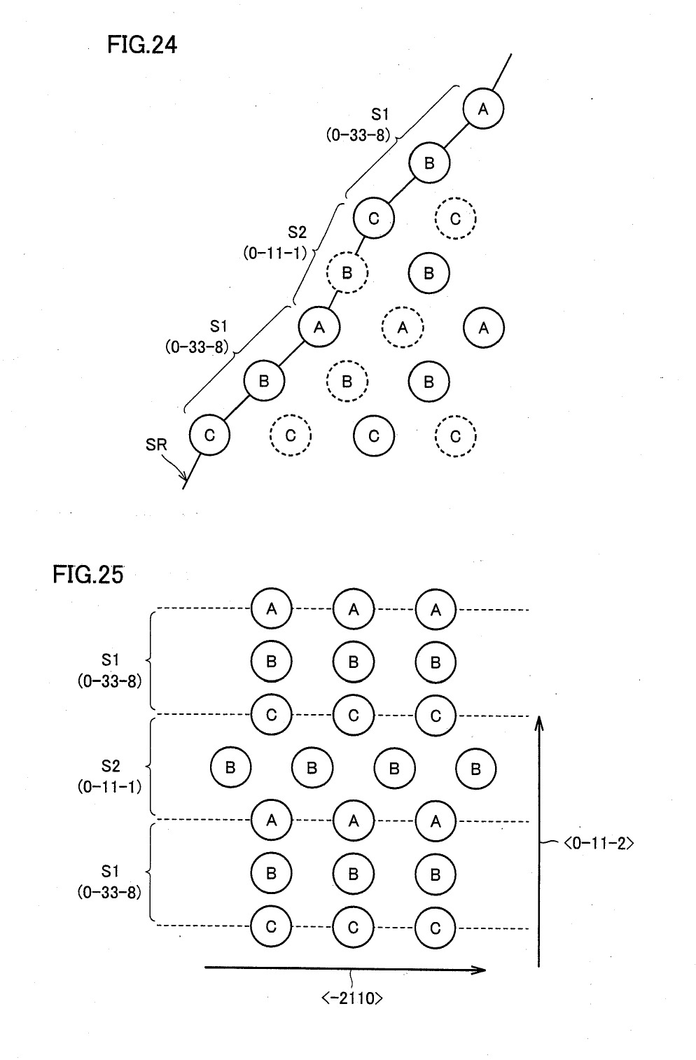

As shown in FIG. 24, combined plane SR is formed by alternately providing planes S1 having a plane orientation of (0-33-8) and planes S2 connected to planes S1 and having a plane orientation different from that of planes S1. Each of planes S1 and S2 has a length twice as large as the interatomic spacing of the S1 atoms (or C atoms). It is noted that a plane with plane S1 and plane S2 being averaged corresponds to the (0-11-2) plane (FIG. 23).

As shown in FIG. 25, when combined plane SR is viewed from the (01-10) plane, the single-crystal structure has a portion periodically including a structure (the portion of plane S1) equivalent to a cubic structure. Specifically, combined plane SR is formed by alternately providing planes S1 having a plane orientation of (001) in the above-described structure equivalent to a cubic structure and planes S2 connected to planes S1 and having a plane orientation different from that of planes S1. Also in polytype other than 4H, the surface can be thus formed of the planes (planes S1 in FIG. 22) having a plane orientation of (001) in the structure equivalent to a cubic structure and the planes (planes S2 in FIG. 22) connected to the foregoing planes and having a plane orientation different from that of the foregoing planes. The polytype may be 6H or 15R, for example.

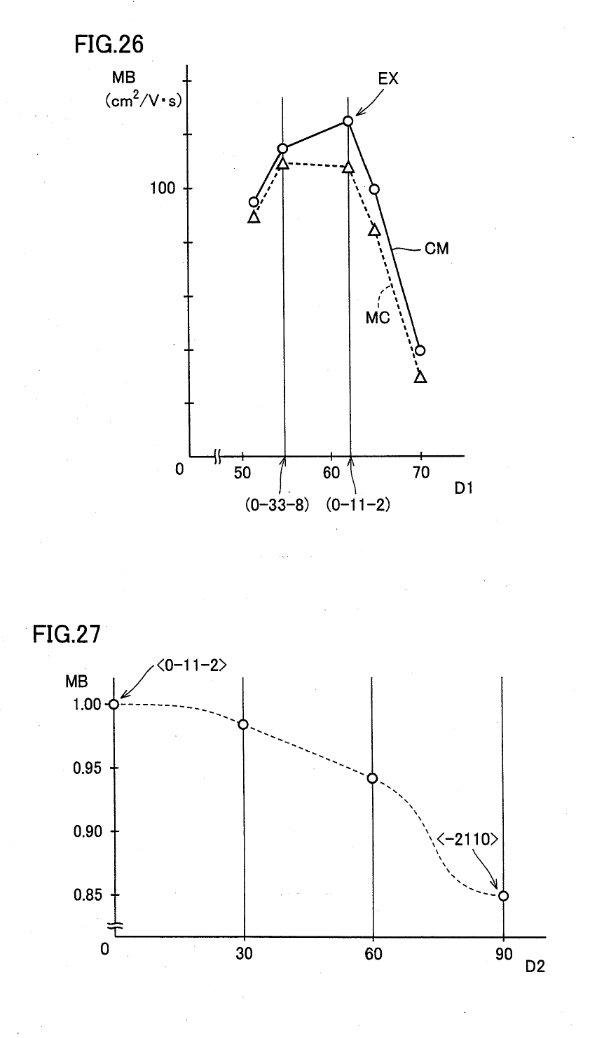

Referring now to FIG. 26, relation between the crystal plane of surface SW and mobility MB in the channel surface is described. In the graph of FIG. 26, the horizontal axis represents an angle D1 formed by the (000-1) plane and the macroscopic plane orientation of surface SW having the channel surface, and the vertical axis represents mobility MB. A group of plots CM corresponds to a case where surface SW is finished to have the special plane through thermal etching, and a group of plots MC corresponds to a case where surface SW is not subjected to such thermal etching.

In group of plots MC, mobility MB is at maximum when the surface of the channel surface has a macroscopic plane orientation of (0-33-8). This is presumably due to the following reason. That is, in the case where the thermal etching is not performed, i.e., in the case where the microscopic structure of the channel surface is not particularly controlled, the macroscopic plane orientation thereof corresponds to (0-33-8), with the result that a ratio of the microscopic plane orientation of (0-33-8), i.e., the plane orientation of (0-33-8) in consideration of that in atomic level, becomes statistically high. On the other hand, mobility MB in group of plots CM is at maximum when the macroscopic plane orientation of the surface of the channel surface is (0-11-2) (arrow EX). This is presumably due to the following reason. That is, as shown in FIGS. 24 and 25, the large number of planes S1 each having a plane orientation of (0-33-8) are densely and regularly arranged with planes S2 interposed therebetween, whereby a ratio of the microscopic plane orientation of (0-33-8) becomes high in the surface of the channel surface.

It is noted that mobility MB has orientation dependency on combined plane SR. In a graph shown in FIG. 27, the horizontal axis represents an angle D2 between the channel direction and the <0-11-2> direction, and the vertical axis represents mobility MB (in any unit) in the channel surface. A broken line is supplementarily provided therein for viewability of the graph. It has been found from this graph that in order to increase channel mobility MB, channel direction CD (FIG. 21) preferably has an angle D2 of not less than 0° and not more than 60°, and more preferably, substantially 0°.

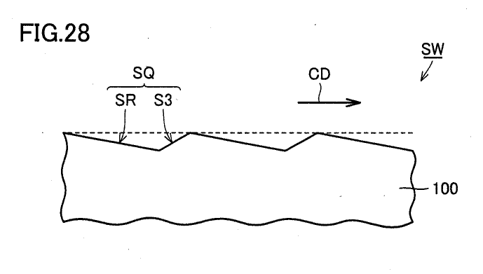

As shown in FIG. 28, surface SW may further include a plane S3 (third plane) in addition to combined plane SR. More specifically, surface SW may include a combined plane SQ formed of periodically repeated planes S3 and combined planes SR. In this case, the off angle of surface SW relative to the {000-1} plane is deviated from the ideal off angle of combined plane SR, i.e., 62°. This deviation is preferably small, and preferably in a range of ±10°. Examples of a surface included in such an angle range include a surface having a macroscopic plane orientation of the {0-33-8} plane. More preferably, the off angle of surface SW relative to the (000-1) plane is deviated from the ideal off angle of combined plane SR, i.e., 62°. This deviation is preferably small, and preferably in a range of ±10°. Examples of a surface included in such an angle range include a surface having a macroscopic plane orientation of the (0-33-8) plane.

Such a periodic structure can be observed, for example, by TEM or AFM.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide semiconductor device comprising:
a silicon carbide substrate including a first layer of a first conductivity type, a second layer of a second conductivity type provided on said first layer, and a third layer of said first conductivity type provided on said second layer and isolated from said first layer by said second layer, said silicon carbide substrate being provided with a trench which is formed through said third layer and said second layer to reach said first layer and which has a bottom on said first layer;
a gate electrode embedded in said trench; and
a gate insulating film separating said silicon carbide substrate from said gate electrode in said trench,
said first layer including a relaxation region sandwiching said gate insulating film between itself and said gate electrode, said relaxation region being doped with a first impurity for providing said first conductivity type, and also being doped with a second impurity for providing said second conductivity type in a concentration lower than that of said first impurity.

2. The silicon carbide semiconductor device according to claim 1, wherein
said relaxation region has a concentration of said second impurity of not less than 1×10¹⁴ cm⁻³.

3. The silicon carbide semiconductor device according to claim 1, wherein
in at least a portion of said relaxation region, a value obtained by subtracting the concentration of said second impurity from the concentration of said first impurity is not more than 10% of the concentration of said first impurity.

4. The silicon carbide semiconductor device according to claim 1, wherein
said relaxation region has a thickness of not less than 200 nm.

5. The silicon carbide semiconductor device according to claim 1, wherein
said trench has a tapered shape and expands toward an opening side.

6. A method for manufacturing a silicon carbide semiconductor device, comprising the steps of:
forming a silicon carbide substrate including a first layer of a first conductivity type, a second layer of a second conductivity type provided on said first layer, and a third layer of said first conductivity type provided on said second layer and isolated from said first layer by said second layer, said first layer being doped with a first impurity to provide said first layer with said first conductivity type;
forming a trench through said third layer and said second layer to reach said first layer and have a bottom on said first layer;
forming a relaxation region on said bottom by implanting a second impurity for providing said second conductivity type through said bottom of said trench into said first layer, said step of forming a relaxation region being performed in such a manner that the concentration of said second impurity is lower than the concentration of said first impurity in said relaxation region;
forming a gate insulating film to cover an inner surface of said trench of said silicon carbide substrate; and
forming a gate electrode on said gate insulating film.

7. The method for manufacturing a silicon carbide semiconductor device according to claim 6, wherein
said step of forming a relaxation region is performed by implanting said second impurity into the entire said inner surface of said trench.
